(19) United States
(12) Patent Application Publication
(10) Pub. No.: US 2003/0094610 A1
(43) Pub. Date: May 22, 2003

(54) Wash water or immersion water used during semiconductor manufacturing

(76) Inventors: Hidemitsu Aoki, Tokyo (JP); Hiroaki Tomimori, Tokyo (JP); Kenichi Yamamoto, Tokyo (JP); Keiji Hirano, Tokyo (JP); Tsutomu Taira, Tokyo (JP); Yukinari Yamashita, Tokyo (JP); Takashi Futatsuki, Tokyo (JP)

Correspondence Address: Jonathan P. Osha, Rosenthal & Osha L.L.P., Suite 2800, 1221 McKinney Street, Houston, TX, 77022, US

(21) Appl. No.: 10/280,951

(22) Filed: Oct. 25, 2002

(30) Foreign Application Priority Data
Oct. 31, 2001 (JP) 2001-334841

(51) Int. Cl. H01L 23/58

(52) U.S. Cl. 257/48

(57) ABSTRACT

A hydrogen dissolving device 2 is connected to a high-purity water processing device 1. Hydrogen is dissolved into the high-purity water in the hydrogen dissolving device 2 to produce hydrogen-dissolved water. The hydrogen-dissolved water is conveyed via a transport line 7 to a wash apparatus 5 or to an immersion apparatus 6. The hydrogen-dissolved water exiting from the transport line 7 inhibits oxidation of semiconductor devices during wash or immersion process.

### BACKGROUND OF THE INVENTION

1. Field of the Invention

The present invention relates to an apparatus for producing wash water or immersion water used during wash or immersion steps of semiconductor devices in the manufacturing process of semiconductor devices. In the present invention, a “semiconductor device” refers to a substrate itself such as a silicon wafer, a substrate with an element formed thereon, and a substrate with an element partially formed on the substrate.

2. Description of the Related Art

In recent years, higher integration in a VLSI (very large scale integration) and higher fineness in wiring have been achieved. For this purpose, in order to increase the degree of integration per unit area, various techniques have been developed for improving flatness of the surface of the substrate and for providing multi-layer wirings, and low resistance materials are being used for the wirings in order to realize high fineness for the wirings.

Most of the components of an LSI are formed on a silicon substrate. A typical manufacturing method of the LSI includes the following steps. Namely, the manufacturing method includes an oxidizing step for forming an oxide film in a high temperature diffusion furnace over the surface of a silicon wafer which has been polished in a mirror-like manner; a photoresist applying step for applying a photoresist (a photosensitive agent) over the insulated film to introduce photosensitivity; an exposing step for covering the wafer with a mask onto which a predefined pattern is drawn and for irradiating light for exposing the photoresist onto the wafer through the mask to print a pattern identical to the pattern drawn on the mask; a developing and etching step for removing the exposed portion only of the resist using a developing agent and immersing the wafer into an etching solution to etch the insulated film of the exposed portion; an impurity diffusing step for injecting an impurity into the silicon surface exposed as a result of the developing and etching step; a metallizing step for creating a metal film layer for forming a wiring over the wafer surface; a patterning step for patterning the formed metal layer to form a metal wiring layer; and so on. When a multi-layer wiring scheme is employed, another insulated film is created over the metal wiring layer and another metal wiring layer is formed over the second insulated film.

As the material for the wiring, aluminum, an alloy of aluminum and copper, and an alloy of aluminum, copper, and silicon have been commonly used. In recent years, the use of a copper wiring is becoming more and more popular because a copper wiring allows for a faster operation. By using a copper wiring, the resistance can be reduced and, at the same time, high reliability can be achieved. The copper wiring, however, poses a problem in that the electron migration is affected. If the electrical resistance is small, the voltage can be reduced, the amount of generated heat can be reduced, and the effective cross sectional area of the wiring can be reduced, and therefore, a material with a low resistance is well suited for high integration.

For high integration, multi-layer wiring techniques are important. When employing a multi-layer wiring, in order to provide, after the first metallizing step, a subsequent wiring layer through a metallizing step similar to the first metallizing step, it is necessary to form an insulated film between the two wiring layers. Through the insulated film, a wiring formed perpendicular to the substrate and commonly referred to as a “plug” is provided to connect the layer above and the layer below.

In some cases, a polishing step may be applied after the metallizing step, in which portions other than the portions that become the wirings are removed. In this polishing step, a polishing liquid agent is used and supplied onto a substrate which is fixed on a turntable and the substrate is polished.

Washing after the polishing step is very important in order to prevent wiring defects caused by remaining pollutants. The pollutants primarily include the residual abrasive grains of polishing step. In order to remove the pollutants, conventionally, high-purity water or an alkali solution having chelate functionality has been used.

In the polishing agent used in the polishing step, polishing grains having grain sizes adjusted to uniform sizes are dispersed in an acidic or an alkali solution. After the polishing, a large amount of polish dusts brought about by the polishing of the substrate and the polishing liquid agent adhere to the substrate, which should quickly be removed by washing. After the polishing, a highly reactive surface is exposed as the oxide film is removed, and therefore, it is desirable that the subsequent manufacturing steps be proceeded quickly. In addition, in some other cases, the semiconductor device maybe immersed and stored in an immersion tank filled with high-purity water until the subsequent manufacturing steps are carried on.

With the current technology, the quality of high-purity water that can be obtained by a typical high-purity water production apparatus used for manufacturing of an LSI of sub-micron design rule is, for example, as indicated in Table 1 shown below. With high-purity water having such quality, it is currently considered that no pollutant attributed to the high-purity water adheres to the surface of the semiconductor device during a rinse treatment by the high-purity water.

TABLE 11

| | |
|---|---|
| ELECTRICAL RESISTIVITY | 18.2 MΩ · cm or greater |
| TOTAL ORGANIC CARBON | 1 μg—C/liter or less |
| NUMBER OF PARTICULATES | 1/milliliter or less |
| | (particle size 0.05 μm or greater) |
| NUMBER OF LIVE MICROBES | 0.1/liter or less |
| SILICA | 0.1 μg—SiO2/liter or less |
| SODIUM | 0.005 μg—Na/liter or less |
| IRON | 0.005 μg—Fe/liter or less |
| COPPER | 0.005 μg—Cu/liter or less |
| CHLORIDE ION | 0.005 μg—Cl/liter or less |
| CONCENTRATION OF HYDROGEN | 7.0 |
| ION (pH) | |
| OXIDATION-REDUCTION | +350 mV(vs. NHE) |
| POTENTIAL (ORP) | |
| CONCENTRATION OF DISSOLVED | 2 μm—0/liter or less |
| OXYGEN (DO) | |

There is however, a problem in the recent manufacturing processes using copper in that because the dimension of the pattern is reduced to 200 nm width and 400 nm thickness, slight corrosion of wiring triggers disconnection of the wiring. As described earlier, an insulated film is formed between the substrate and the wiring layer or between two wiring layers in order to prevent short circuits. In general, when the substrate is made of silicon, a silicon oxide film could function as the insulated film. This is particularly true when the silicon oxide film is formed with a uniform thickness. However, as a result of reduction in the thickness of the insulation oxide film in the high fineness wiring, the variation in the insulation characteristics resulting from the variation in the thickness of the oxide film must be controlled or managed much more strictly.

### SUMMARY OF THE INVENTION

While the corrosion of the wiring and the variation in the thickness of the oxide film as described above each causes unexpected product defects, it is difficult to detect these problems immediately after they occur, and, thus, in many cases, malfunctions are only detected at the stage of product inspection. One phenomenon that can be considered as a cause for these malfunctions such as the corrosion of the wiring and the variation in the thickness of the oxide film is an oxidation of the semiconductor substrate or of the wiring during a wash process or an immersion process.

The semiconductor substrate and the wiring which are metals are oxidized in an oxidizing atmosphere, and thus, are transformed from an electrically conductive material or semiconductive material to a material which is virtually an insulator. Moreover, the oxidized metals are more easily dissolvable in water. During the manufacturing process of a semiconductor device, the semiconductor device is exposed to an acidic or an oxidizing atmosphere in many occasions. The present inventors have noticed that an unexpected oxidation also occurs during the wash process or the immersion process utilizing high-purity water, and have also found the cause and a method for inhibiting this phenomenon.

Because of the higher fineness in the semiconductor devices in recent years, even a slight oxidation of a semiconductor substrate or of a wiring, not only by oxidizing atmosphere such as oxygen in the air, but also by oxidizing materials such as oxygen within the high-purity water used for the wash process or the immersion process, can become a problem. In particular, in a ultraviolet oxidation device used for decomposing organic substances among the processing steps for the high-purity water, ultraviolet rays having a central wavelength of 185 nm is irradiated. In this process, the irradiated ultraviolet rays also decompose water molecules to produce hydrogen peroxide and hydroxyl radial which are both oxidizing materials. Of these, hydroxyl radical has a very short life, but most of hydrogen peroxide remains without decomposition and reaches the wash apparatus or to the immersion apparatus. Measurements by the present inventors through the phenolphthalein method indicated that the concentration of hydrogen peroxide in high-purity water produced with the irradiation of ultraviolet rays was 14 μg/L while the concentration of hydrogen peroxide in high-purity water produced by the same apparatus but without operating the ultraviolet irradiating device, that is, high-purity water produced without the irradiation of ultraviolet rays was 2 μg/L or less. This value of “2 μg/L or less” means a value less than the detection limit.

A characteristic of the present invention is that hydrogen-dissolved water is used as wash water or immersion water for use in the wash process or immersion process during manufacturing processes of semiconductor devices. In this manner, oxidation of the semiconductor or the wiring can be inhibited.

According to the present invention, it is possible to provide a design which is compatible with high-purity water production devices currently placed in semiconductor manufacturing lines and which inhibits oxidation of semiconductor devices in wash process and in immersion process of the semiconductor devices. In this description, the present invention is described as applicable to a high-purity water production device, but the present invention is not limited to a high-purity water production device and can also be applied to a deionized water production device.

### BRIEF DESCRIPTION OF THE DRAWINGS

FIG. 1 is a schematic diagram showing a first preferred embodiment of the present invention.

FIG. 2 is a schematic diagram showing a second preferred embodiment of the present invention.

FIG. 3 is a schematic diagram showing a third preferred embodiment of the present invention.

FIG. 4 is a schematic diagram showing a fourth preferred embodiment of the present invention.

FIG. 5 is a schematic diagram showing a fifth preferred embodiment of the present invention.

FIG. 6 is a schematic diagram showing a sixth preferred embodiment of the present invention.

FIG. 7 is a graph showing a relationship between the pH of wash water and the amount of copper elution.

FIG. 8 is a graph showing a relationship between the concentration of dissolved hydrogen in wash water and the amount of copper elution.

FIG. 9 is a schematic, vertical cross sectional view of a semiconductor device having a metal wiring layer.

FIG. 10 is a schematic, vertical cross sectional view of a gate electrode section.

FIG. 11 is an enlarged view of significant sections of the gate electrode section shown in FIG. 10.

### DESCRIPTION OF PREFERRED EMBODIMENTS

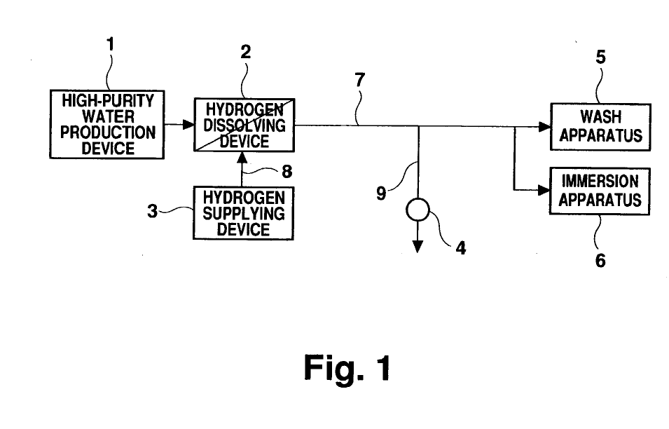

FIG. 1 is a schematic diagram showing basic structures of the present invention. Reference numeral 1 denotes a high-purity water production device, reference numeral 2 denotes a hydrogen dissolving device, reference numeral 3 denotes a hydrogen supplying device, reference numeral 4 denotes a concentration meter for dissolved hydrogen, reference numeral 5 denotes awash apparatus, and reference numeral 6 denotes an immersion apparatus. As will be described below, the high-purity water production device 1 comprises a primary deionized water production device and a secondary deionized water production device. In the present invention, the water to which the hydrogen is dissolved is not limited to high-purity water and primary deionized water may be used instead. Therefore, a primary deionized water production device may be used in place of the high-purity water production device 1, although the preferred embodiments will be described for the case wherein a high-purity water production device is used.

High-purity water supplied from the high-purity water production device 1 is allowed to contact, within the hydrogen dissolving device 2, hydrogen so that hydrogen dissolves into the high-purity water to produce hydrogen-dissolved water. A transport line 7 is provided between the hydrogen dissolving device 2 and the wash apparatus 5 and between the hydrogen dissolving device 2 and the immersion apparatus 6 to convey the hydrogen-dissolved water to the wash apparatus 5 and the immersion apparatus 6. The hydrogen-dissolved water is transported to the wash apparatus 5 for use as the wash water, or, alternatively, is transported to the immersion apparatus 6 for use as the immersion water. In the present invention, the hydrogen-dissolved water may be transported to one or both of the wash apparatus and the immersion apparatus, and therefore, it can be arbitrarily selected whether the hydrogen-dissolved water is used for the sole purpose of washing semiconductor device or the sole purpose of immersion, or the hydrogen-dissolved water is used for both wash and immersion purposes.

The high-purity water production device 1 comprises a primary deionized water production device for obtaining primary deionized water by treating raw water with a coagulation and sedimentation device, a sand filter, an activated charcoal filter, a reverse osmosis membrane device, a two-bed 3-tower ion exchange system, a mixed-bed ion exchange system, and a precision filter, etc., and a secondary deionized water production apparatus for obtaining secondary deionized water by storing the primary deionized water in a primary deionized water tank and then treating the primary deionized water with an ultraviolet oxidation device, a cartridge polisher, and a membrane treatment device such as a ultrafiltration device and a reverse osmosis membrane device and so forth. By applying a secondary treatment to the primary deionized water, it is possible to remove remaining particulates, colloidal materials, organic substances, metals, anions, etc. as much as possible to obtain high-purity water.

The hydrogen dissolving device 2 is a device for dissolving hydrogen into the high-purity water, and is connected through a pipe 8 to the hydrogen supplying device 3 for supplying hydrogen. It is preferable that a gas-liquid separation membrane module charged with a gas dissolving membrane such as a spiral membrane and a hollow fiber membrane be used for the hydrogen dissolving device 2. In the case of a hollow fiber membrane, hydrogen is introduced to the inside or the outside of the hollow fiber membrane and the high-purity water is introduced to the outside or the inside of the hollow fiber membrane. Hydrogen permeates through the membrane and dissolves into the high-purity water, to thereby produce hydrogen-dissolved water.

The hydrogen dissolving device 2 is not limited to the gas dissolving device having the gas dissolving membrane as described above, and any other structure may be utilized as long as hydrogen can be dissolved into the high-purity water in an air-tight system. For example, a device in which hydrogen is dissolved using a line mixer or a device in which hydrogen is dissolved using a stirring pump or the like may be used.

In this manner, by adding the hydrogen into the high-purity water in an air-tight system, it is possible to prevent dissolution of oxygen and carbon dioxide in the air into the high-purity water.

As the hydrogen supplying device 3, it is possible, for example, to allow the water to be treated (high-purity water) to contact hydrogen in gaseous state using a hydrogen gas bottle or a water electrolysis device, or, to prepare hydrogen-dissolved water in advance having a higher concentration of dissolved hydrogen than the desired concentration of dissolved hydrogen in the hydrogen-dissolved water and to mix the prepared hydrogen-dissolved water into the water to be treated (high-purity water). The water electrolysis device comprises an electrolysis cell in which an anode and a cathode are placed with a diaphragm in between, and supplies hydrogen generated in the cathode chamber due to the electrolysis into the hydrogen dissolving device 2.

The concentration meter 4 is a device for measuring the concentration of dissolved hydrogen in sample water collected through a branch pipe 9. With the concentration meter 4, the concentration of dissolved hydrogen in the hydrogen-dissolved water supplied to the wash apparatus 5 or to the immersion apparatus 6 can be measured. The sample water after the concentration measurement is discarded outside the system.

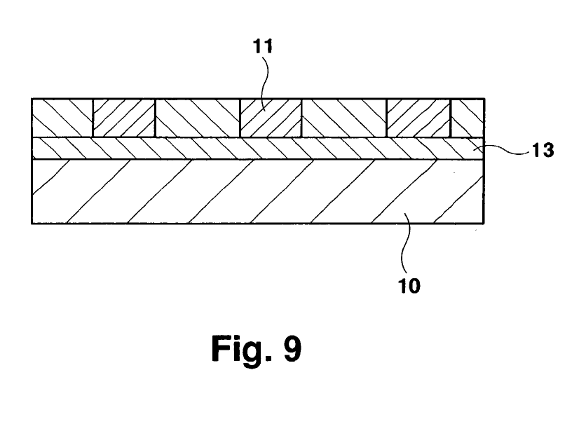

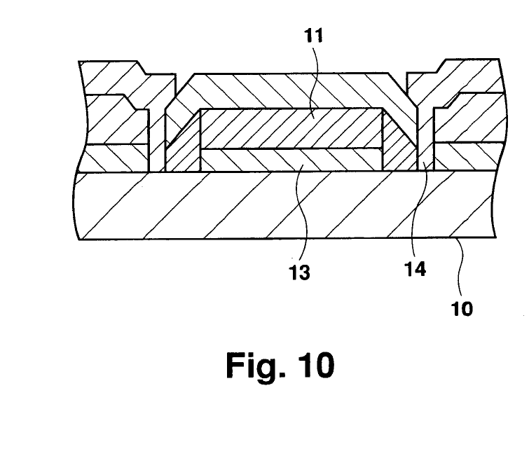

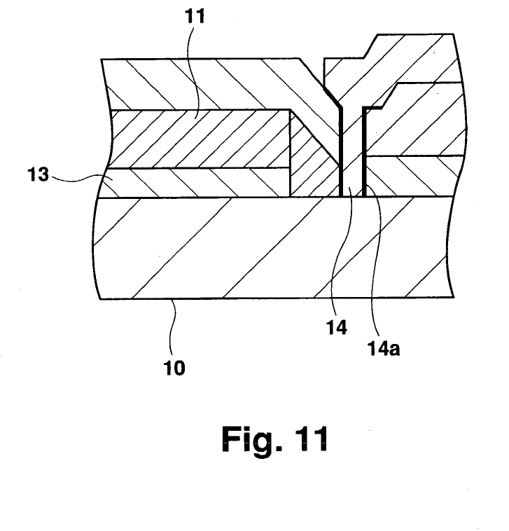

FIGS. 9 and 10 respectively show an example of a semiconductor device. FIG. 9 shows a structure in which a metal wiring is formed through a manufacturing process to which the hydrogen-dissolved water produced using the producing apparatus of the present invention and having oxidation inhibiting effect can suitably be applied. As shown in FIG. 9, an insulated film 13 is formed on a semiconductor substrate 10 and a metal wiring layer 11 is formed on the insulated film 13. Processing of a substrate into such semiconductor substrate is performed as follows. Namely, an insulated film comprising an oxide film or a nitride film is formed in a high temperature diffusion furnace over a surface of a semiconductor substrate having the surface polished in a mirror-like manner, a photoresist (photosensitive agent) is applied over the surface of the insulated film, a mask onto which a pattern is drawn is provided to cover the wafer, light for exposing the photoresist is irradiated onto the photoresist through the mask to expose the portion onto which the light is irradiated in a case of positive type resist, and the exposed portion is dissolved using a solvent. Further, by immersing the semiconductor substrate in warm phosphoric acid and hydrofluoric acid, the portions to which the wiring is to be formed are removed so that a recessed section is formed and the wiring metal and oxide film are formed in the recess section to obtain a semiconductor substrate having a metal wiring layer as shown in FIG. 9. In a case of a multi-layer wiring, another insulated film is formed and the steps similar to the above are repeated to obtain a semiconductor device having another metal wiring layer. A typical material for the semiconductor substrate 10 is a silicon wafer. FIG. 10 shows a gate electrode section and a contact hole section 14 formed through another manufacturing process for which the hydrogen-dissolved water produced by the production apparatus of the present invention and having oxidation inhibiting effect can be suitably applied. An insulated film 13 shown in FIG. 10 is the gate insulated film, the thickness of which must be strictly controlled. As shown in FIG. 11 which is an enlarged view of the important sections of FIG. 10, the recess section illustrated with a bold line represents a contact hole 14a. FIG. 11 shows a structure in which the contact hole 14a is already filled with the wiring metal. Because the contact hole section 14 penetrates through the insulated film and contacts the silicon surface, formation of an insulated oxide film on this contact surface must be avoided.

In many cases, washing is performed before the film formation or etching, or after the polishing process of the metal coating film, in order to remove the particulates, metals, and ion constituents remaining on the semiconductor device. In this wash step, the hydrogen-dissolved water is transported, as wash water, through the transport line 7 to the wash apparatus 5 where the semiconductor device is washed. As the wash apparatus 5, an apparatus in which a semiconductor device is submerged and washed in a wash tank filled with the wash water, an apparatus in which the wash water flows over the semiconductor device to wash the semiconductor device, etc. can be used.

In some cases, the wash process is not necessarily performed immediately after the polishing process of the metal coating film, but rather, the semiconductor device is immersed and stored after the polishing process until the wash process is to be performed. In this immersion process, the hydrogen-dissolved water is transported, as immersion water, through the transport line 7 to the immersion apparatus 6 where the semiconductor device is immersed. The immersion apparatus 6 typically comprises an immersion tank storing the immersion water, and the semiconductor device is immersed into the immersion tank.

As described, the wash process in the present invention is performed using a device structure comprising a hydrogen dissolving device 2 for dissolving hydrogen into high-purity water, a transport line 7 for transporting the hydrogen-dissolved water obtained using the hydrogen dissolving device 2, and a wash apparatus 5 connected to the transport line 7. Similarly, the immersion process in the present invention is performed using a device structure comprising a hydrogen dissolving device 2 for dissolving hydrogen into high-purity water, a transport line 7 for transporting the hydrogen-dissolved water obtained using the hydrogen dissolving device 2, and an immersion apparatus 6 connected to the transport line 7.

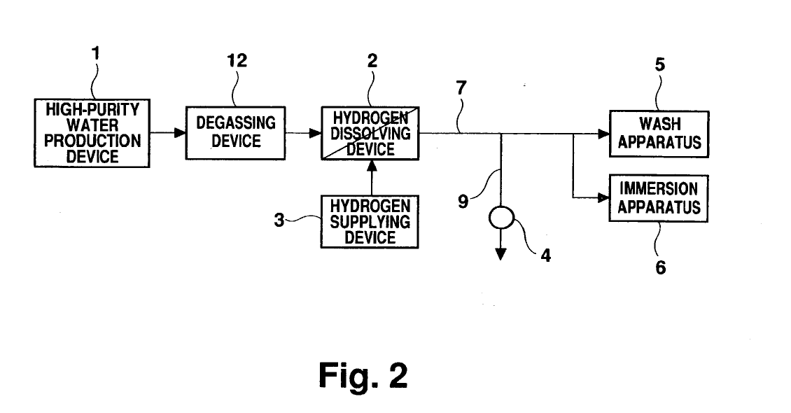

As shown in FIG. 2, a degassing device 12 may be provided upstream of the hydrogen dissolving device 2. As the degassing device 12, a membrane degassing device having a gas permeation membrane, a vacuum degassing device which removes dissolved gases by depressurizing, etc. can be used. Because the degassing device 12 allows additional removal of oxidizing or acidic gases such as nitrogen, oxygen, and carbon dioxide which compose a large portion of the dissolved gases, such configuration is desirable as it allows further effects of oxidation inhibition which is an object of the present invention. Moreover, due to the degassing process, the partial pressure of the dissolved gas within the water to be treated is reduced which facilitates dissolution of hydrogen by the hydrogen dissolving device 2, and thus, it is possible to produce wash water or immersion water having a higher concentration of dissolved hydrogen.

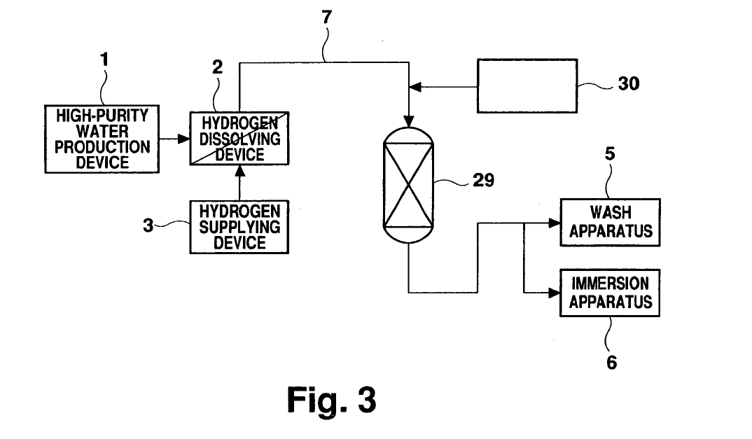

FIG. 3 shows another preferred embodiment of the present invention wherein a palladium catalyst column 29 and a hydrogen-dissolved water supplying section 30 are provided downstream of the hydrogen dissolving device 2. The palladium catalyst column 30 may alternatively be provided upstream of the hydrogen dissolving device 2. In order to remove oxidizing materials in the palladium catalyst column 29, supply of hydrogen is essential. When the palladium catalyst column 29 and the hydrogen water supplying section 30 are provided upstream of the hydrogen dissolving device 2, by supplying hydrogen in an amount exceeding the amount necessary for reaction of hydrogen and the oxidizing materials, it is possible to obtain treated water having excess hydrogen at the exit of the palladium catalyst column 29.

In this configuration, the palladium catalyst column 29 is provided primarily to remove dissolved oxygen in the high-purity water.

More specifically, by adding hydrogen to the water to be treated before the water to be treated is passed through the palladium catalyst, 1 mole of dissolved oxygen in the water to be treated is bonded to 2 moles of hydrogen to produce water, and, thus, deoxidation can be achieved. One of the objects of the present invention is to remove the oxidizing materials, and therefore, the materials to be removed from the water to be treated include, in addition to the dissolved oxygen, hydrogen peroxide produced by irradiation of ultraviolet rays. The position where the water to be treated should be made in contact with the palladium catalyst section may be anywhere behind the ultraviolet oxidation device as this configuration allows for removal of hydrogen peroxide produced by the ultraviolet oxidation device. For example, the palladium catalyst section may be provided downstream of the hydrogen dissolving section. This configuration is desirable as the structure can be simplified by not requiring a separate hydrogen adding section because hydrogen for reaction with oxygen or with hydrogen peroxide is already present in the water to be treated. When the palladium catalyst section is provided in front of the hydrogen dissolving section, the palladium catalyst section may be provided anywhere in front or in rear of a cartridge polisher or a ultrafiltration membrane each of which is provided behind the ultraviolet oxidation device in the high-purity water processing device. Because the present invention provides a hydrogen dissolved water producing apparatus in order to inhibit oxidation, it is desirable to supply hydrogen in an amount in excess to the completion of the reaction of oxygen and hydrogen in 1 mole to 2 moles ratio so that in addition to the removal of oxygen and removal of hydrogen peroxide, hydrogen-dissolved water can be obtained.

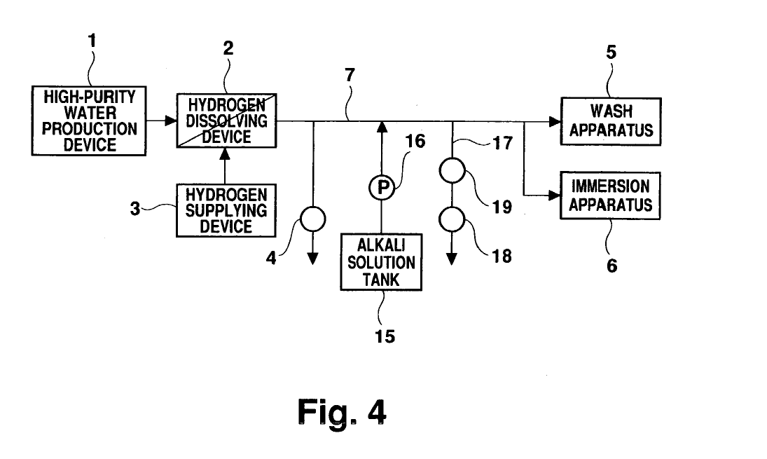

According to another preferred embodiment of the present invention, an alkali solution is added to the wash water or immersion water. The embodiment in which an alkali solution is added is shown on FIG. 4. As shown in FIG. 4, an alkali solution tank 15 is connected to the transport line 7 and an alkali solution is added from the alkali solution tank 15 to the hydrogen-dissolved water through a pump 16 for sending the alkali solution. A pH measuring device 18 is provided for sampling a sample solution through a branch pipe 17 and for measuring the pH of the hydrogen-dissolved water to which the alkali solution is added. Because the addition of the alkali solution is desired for the wash water or for the immersion water, the position where the alkali solution is added may be in front of the hydrogen dissolving device 2, or, alternatively, when different pHs are desired for the wash apparatus 5 and for the immersion apparatus 6, the alkali solution adding sections and corresponding pH measuring devices may be provided separately in each line extending to each of these processing apparatuses in front of these processing apparatuses.

By adding an alkali solution to the hydrogen-dissolved water, it is possible to lower the oxidation-reduction potential of the hydrogen-dissolved water further towards negative side to increase the reducibility, resulting in further inhibition of oxidation of the gate insulated film and wiring on the semiconductor device. In FIG. 4, reference numeral 19 represents an ORP (oxidation-reduction potential) measuring device. It is preferable that the pH is adjusted through addition of alkali to a value of 9.5 or less. It is more preferable that the pH be adjusted to a value between 8.5 and 9.5. In the rinsing process, it is preferable that the pH be adjusted to a value between 7.4 and 7.6, and in the other processes, that is, in the wash process or in the immersion process, the pH is preferably adjusted to a value between 8.5 and 9.0.

An advantage of such adjustment of the quality of water to alkaline is that when the added alkali does not chemically react in the aqueous solution, the solution becomes alkaline, and thus, it is possible to make the oxidation-reduction potential more reducible. This is preferable in the present invention which aims to inhibit oxidation. Moreover, similar to the hydrogen dissolving step in the hydrogen dissolving section which is performed in an air-tight system to prevent dissolution of oxygen and carbon dioxide from the air, the alkali addition is also performed in an air-tight system to prevent dissolution of oxygen and carbon dioxide from the air. Therefore, the method of adding an alkali solution is also preferable.

The kind of the alkali solution described herein is not necessarily limited. However, it is preferable to use an alkali solution that does not contain any metal element, such for example as ammonium hydroxide (NH₄OH) and tetramethyl ammonium hydroxide (TMAH).

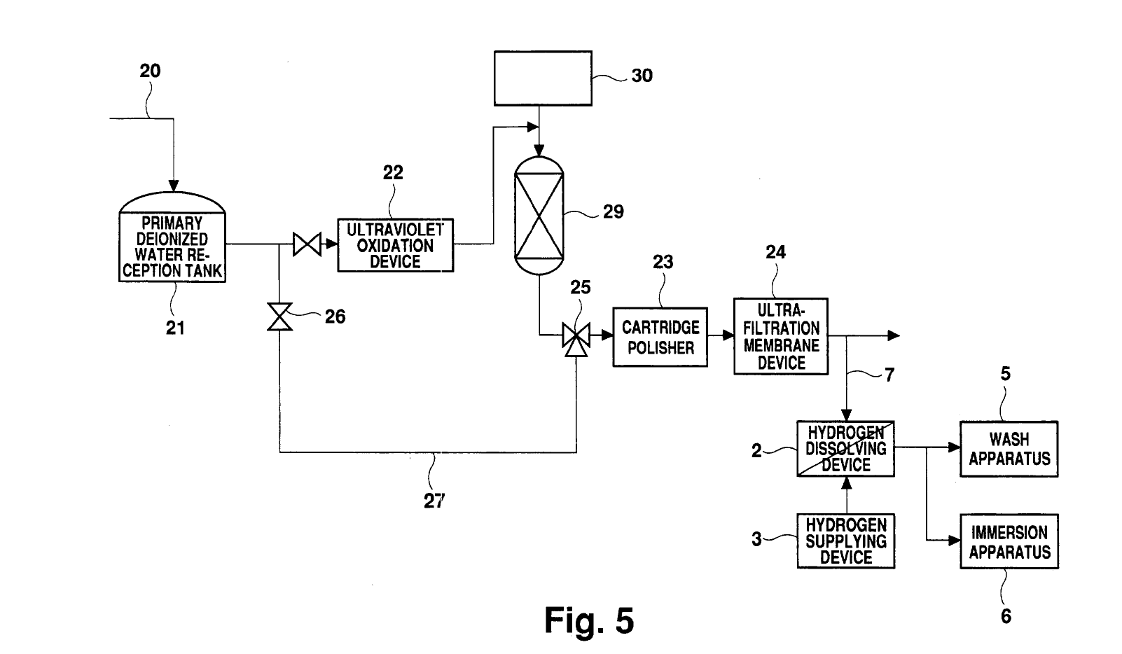

In another preferred embodiment of the present invention, a bypass line is provided in the high-purity water production device to bypass the ultraviolet oxidation device which irradiates ultraviolet rays having a central wavelength of 185 nm onto the water to be treated. This configuration allows for selective supply, to the hydrogen-dissolved water producing section, of either the high-purity water which has been subjected to the ultraviolet oxidation treatment or feed water for hydrogen-dissolved water (primary deionized water) via the bypass line. FIG. 5 shows an example of this configuration with the bypass line. In the production steps of the high-purity water, typically, the primary deionized water is passed through the ultraviolet oxidation device 22 so that TOC (total organic carbon) is decomposed. However, as described above, in the ultraviolet oxidation device, oxidizing materials such as hydrogen peroxide is generated. In this embodiment, a bypass pipe 27 is provided in front of the ultraviolet oxidation device and is connected to the line in front of a cartridge polisher 23. With such a configuration, it is possible to prevent mixture of hydrogen peroxide into the hydrogen dissolving device and to supply hydrogen-dissolved water in which oxidation is highly inhibited to the wash apparatus 5 or to the immersion apparatus 6, which is an object of the present invention. The position where the bypass pipe for bypassing the ultraviolet oxidation device is connected again to the secondary system line is not limited as long as the position is behind the palladium catalyst column 29 and the hydrogen water supplying section 30 for adding hydrogen to the palladium catalyst. For example, the bypass pipe 27 may be connected between the cartridge polisher 23 and the ultrafiltration device 24, between the ultrafiltration device and the hydrogen dissolving apparatus 2. In FIG. 5, reference numeral 20 represents a supply pipe for primary deionized water, reference numeral 21 represents a reception tank for the primary deionized water, reference numeral 25 represents a three-way switching valve, and reference numeral 26 represents a valve.

As described before, even when high-purity water which has been treated to have such high purity as to allow use for washing semiconductor devices is utilized, if ultraviolet rays with a central wavelength of 185 nm is irradiated during the production process, a minute amount of hydrogen peroxide is generated and the semiconductor substrate and the wiring may be oxidized. In this embodiment, a unique device structure is provided for solving this problem. Namely, in this embodiment, a configuration is presented in which a bypass pipe for bypassing the ultraviolet oxidation device for irradiating ultraviolet rays with a central wavelength of 185 nm, which gives rise to a minute amount of oxidizing materials, is provided alongside the pipe which carries water (primary deionized water) which is subjected to the ultraviolet oxidation treatment. The ultraviolet oxidation device with a central wavelength of 185 nm is provided in order to decompose the TOC compositions in the water (primary deionized water) to be treated. Therefore, in the configuration of the present embodiment, the water to be treated without the TOC compositions decomposed is supplied to the hydrogen dissolving section and further to the wash apparatus or to the immersion apparatus for the semiconductor substrate and wiring. However, after extensive experiments and reviews, the present inventors have found that even when the semiconductor substrate and wiring are washed using hydrogen-dissolved water produced from the water (primary deionized water) to be treated without TOC compositions decomposed, the occurrence probability of product defects is not significantly higher compared to the case where the semiconductor substrate and the wiring are washed using hydrogen-dissolved water produced from water (primary deionized water) to be treated which has been subjected to the ultraviolet irradiation. The present inventors have also found that the oxidation of the semiconductor substrate and the wiring can also be inhibited with the configuration of the present embodiment.

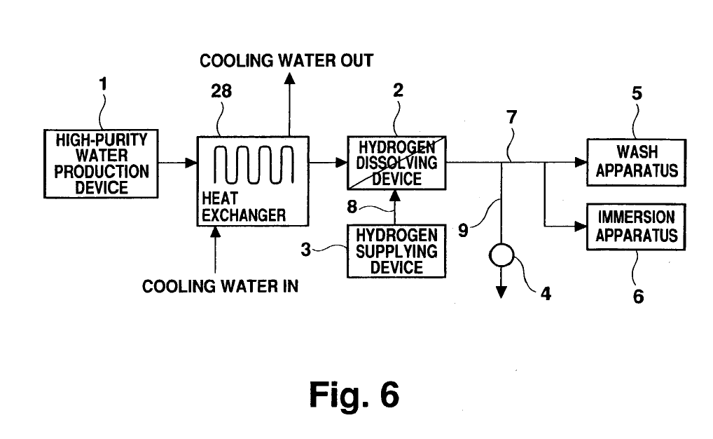

In another embodiment of the present invention, it is possible to lower the temperature of high-purity water to be supplied to the hydrogen dissolving section in advance to increase the saturation solubility of hydrogen. This configuration is shown in FIG. 6. In addition to the basic structures shown in FIG. 1, the configuration of FIG. 6 is provided with a heat exchanger 28 as a temperature control section in front of the hydrogen dissolving section. With such a configuration, it is possible to increase the saturation solubility of hydrogen gas by lowering the water temperature without adjusting any conditions other than the water temperature. In addition, the configuration also has an advantage that reactions such as oxidation and dissolution can also be inhibited at a low temperature. Typically, the temperature of high-purity water is between 20° C. and 25° C. It is preferable that the temperature be lowered to a temperature between 10° C. and 15° C. using the heat exchanger 28.

The solubility of hydrogen to water is similar to other gases, and is increased as the water temperature is decreased. As described above, in the present invention, it is preferable to make the wash water or immersion water reductive. With a decrease in the water temperature, it is possible to increase the concentration of dissolved hydrogen without changing the feeding mechanism or adding mechanism of hydrogen, and thus, this configuration is preferable.

It is preferable that the concentration of dissolved hydrogen in the hydrogen-dissolved water be 50 μg H/L or more, and less than or equal to the saturation solubility.

The concentration of dissolved hydrogen varies depending on the environment in which the hydrogen-dissolved water is used. When the hydrogen-dissolved water is used as immersion water, degassing of hydrogen within the immersion tank causes bubbles to adhere onto the surface of the immersed device, and, consequently, causes difference in surface conditions for the portions to which bubbles are adhered and the portions in contact with water. Therefore, it is desirable that the amount of dissolved hydrogen be less than or equal to the saturation solubility. Also, during a washing process in which a ultrasonic wave is irradiated in a tank, with wash water supersaturated with hydrogen gas, in addition to a disadvantage of reduction in the effects through absorption of the ultrasonic waves by the dissolved gas, there is a disadvantage that degassing within the tank and bubbles adhering to the surface of the device to be washed occur. Therefore, it is desirable that the amount of dissolved hydrogen be less than or equal to the saturation solubility. Here, no explicit value for the maximum of the desirable range of the amount of dissolved hydrogen is described, but instead, the maximum of the desirable range is described as the saturation solubility. This is because the maximum varies depending on conditions such as the water temperature and the water pressure when the hydrogen-dissolved water is used. For example, the amount of hydrogen gas completely dissolvable when the water temperature is 10° C. may cause a supersaturated state when the water temperature is raised to 30° C., and consequently, may cause generation of bubbles, unsatisfactory washing, and unsatisfactory application of ultrasonic waves. The saturation solubility of hydrogen at a water temperature of 10° C. is 1.76 mg H/L and that at a water temperature of 30° C. is 1.47 mg H/L.

The minimum value of 50 μg H/L is set because the present inventors have found that at any concentration of dissolved hydrogen lower than this value, no significant inhibition effects of oxidation was observed, and, in addition, the variation in wash effects during the washing tests was high, that is, stable wash process could not be performed. The exact reason for the variation in wash effects is not yet known, but the present inventors suspect that because the degree of dissolution of the oxygen and carbon dioxide from air is not stable at the wash or immersion process, reduction in the partial pressure of hydrogen within the hydrogen-dissolved water becomes significant when the degree of dissolution of oxygen and carbon dioxide is high, causing loss of the reductive property of the wash or immersion water and consequent reduction in the oxidation inhibiting effects.

In this embodiment, it is preferable that the pH of the hydrogen-dissolved water to which the alkali solution is added be in a range from 7.4 to 9.5.

In the present embodiment, an alkali solution is added to the hydrogen-dissolved water in which hydrogen peroxide is removed by the treatment at the palladium catalyst section to adjust the pH of the hydrogen-dissolved water to a specific range of pH. An object of employing such a structure is inhibition of charging during the wash or immersion process of semiconductor substrate or wiring. When adjusting the pH to alkaline, typically, an alkali agent is added to the hydrogen-dissolved water. The alkali agent is dissociated in the aqueous solution and raises the electrical conductivity of the aqueous solution. In other words, the dissociation of the alkali agent facilitates flow of electricity in the solution, but hydrogen-dissolved water does not change the electrical conductivity of the water to be treated during its production process, and thus, can maintain the properties of the high-purity water which is known to be easily charged. By adding alkali to the hydrogen-dissolved water, the oxidation-reduction potential can be reduced towards the reducing side, and, at the same time, charging can be inhibited.

The minimum limit of the pH range which is a pH of 7.4 is preferable as a value for hydrogen-dissolved water used primarily in a rinsing process. The wash water used in rinsing (may also be referred to as “rinse water”) preferably does not contain any impurity in order to avoid residual impurities such as ion constituents to the surface of the device to be washed after the rinsing. However, for the purpose of making the wash water more reductive in order to inhibit adverse effects due to oxidation, it is effective to add a slight amount of alkali. Through experiments, the present inventors have found that any pH lower than this pH value (7.4) does not show any advantage over the case when no alkali is added, and moreover, because at any pH lower than this pH, the alkali concentration is low, adjustment of the alkali agent and stable measurement of pH were difficult. Therefore, from both the point of view of the advantages and of the simplicity of the device structure, any pH lower than 7.4 is not desirable. On the other hand, with any pH higher than the maximum limit of the pH range which is 9.5, although the effect of lowering the oxidation-reduction potential is larger due to the high pH value, such pH is not preferred as it may cause etching or alkali corrosion of the silicon substrate.

As described, an object of the present invention is to prevent oxidation of the semiconductor substrate or the wiring. Because the cause of the oxidation is the oxidizing materials in the wash water or immersion water, it is necessary to prevent dissolution of oxygen and carbon dioxide from air to the wash water or immersion water, not only when the wash water or immersion water is produced, but also during the wash or immersion process. That is, if the wash water or immersion water becomes acidic or oxidizing, the reductive property of the hydrogen-dissolved water is deteriorated, causing oxidation of the semiconductor substrate or the wiring. Therefore, dissolution of oxidizing or acidic materials to the wash water or immersion water must be prevented. For the purpose of preventing dissolution of oxidizing or acidic materials into the wash water or immersion water, it is possible to fill the wash processing chamber or the immersion processing chamber with hydrogen gas in order to prevent contact of the device to be processed and the air in the wash processing device or immersion processing device.

One of the most suited application of wash or immersion by wash water or immersion water is a formation process of a gate insulated film of a MOS transistor. With the development of higher performance semiconductor elements, the required thickness of the gate insulated film is becoming smaller and smaller. In particular, in a logic type device, a very thin thickness of 1.5 nm-2.0 nm is required for the insulated film (silicon oxide film or silicon nitride film). The insulated film is typically formed on a clean surface obtained by removing a naturally formed oxide film on a silicon substrate by an HF type solution. However, it has been reported that the naturally formed oxide film forms and grows again during rinsing process with deionized water after the treatment using the HF type agent. The thickness of this naturally formed oxide film is reported to be approximately 0.5 nm-1.0 nm, a value which cannot be ignored for a very thin gate insulated film. It is considered that this re-formation of oxide film is due to oxygen in the air mixed during the rinse treatment by deionized water or due to the fact that the deionized water itself contains a slight amount of oxidizing materials such as hydrogen peroxide. Therefore, prevention of this re-oxidation becomes more and more important for the wash water.

It is preferable that the manufacturing process of semiconductor device is a contact hole formation process for exposing a silicon surface.

Of various semiconductor devices, in a MOS transistor, an electric current flows between a source electrode and a gate electrode when a voltage is applied to the gate electrode. Therefore, for each of the source and gate electrodes, a hole commonly referred to as a “contact hole” is provided on the interlayer insulated film and is filled with a wiring metal in order to make the electrode in contact with a semiconductor which is made of, for example, silicon. As is apparent, it is not desirable that an insulated oxide film be formed on the semiconductor substrate during this formation process of the contact holes. In other words, the wash water or immersion water of the present invention having oxidation inhibition effect is useful in this process. The contact hole is formed not only for the source electrode and the gate electrode, but also for allowing contact between the gate electrode and a gate polycrystalline silicon. The gate polycrystalline silicon is not the semiconductor substrate itself, but, obviously, formation of an oxide film, which increases the electrical resistance, in the contact hole section formed for contact between the gate electrode and the gate polycrystalline silicon which is a path for electrical conductive is not desirable. Therefore, the wash water or immersion water presented in the present invention having oxidation inhibition effect is also useful in the formation process of the contact hole between the gate electrode and gate polycrystalline silicon.

In another embodiment of the present invention, the manufacturing process of the semiconductor device is preferably a formation process of a wiring layer made of a metal including copper or an etching process of an insulated film formed on a wiring made of a metal including copper.

In this embodiment, the manufacturing process is specified to a process for forming a wiring layer including copper and an etching process of an insulated film formed over a wiring made of a metal including copper, each of which is one of the most suitable applications of the wash or immersion process by the wash water or immersion water. As described before, the requirements for the thickness of the gate oxide film is becoming smaller and smaller as the performance of the semiconductor elements is improved. Similarly, in the metal wiring layer, the required width of the wiring is becoming narrower and the required thickness is becoming thinner, and, moreover, the thickness requirement for insulated film formed on the wiring is also becoming smaller. For processing these very fine and very thin structures, even a slight oxidation during the wash or immersion process may cause a fatal dissolution of the wiring material or variation in the thickness of the oxide film. Furthermore, with regard to the dissolution of the wiring, the change in the wiring material being used is one of the reasons that is increasing the seriousness of the effects of the oxidation. More specifically, the dimensions of wiring have been reduced in order to realize higher integration of the semiconductor products. It is necessary, however, to also simultaneously respond to the demands for higher speed and lower power consumption. With regard to the demand for higher speed, even a CPU equipped in a personal computer commercially available nowadays has an operational clock speed exceeding 1 GHz. In order to achieve higher speed and lower power consumption, it is necessary to use a material having a low resistance as the material for the wiring. As a result, in logic type devices, copper wirings are used instead of the conventionally used copper alloy wirings. Because the copper wiring is very easily oxidized, the use of the wash or immersion water of the present invention having oxidation inhibition effects for the copper wiring is effective.

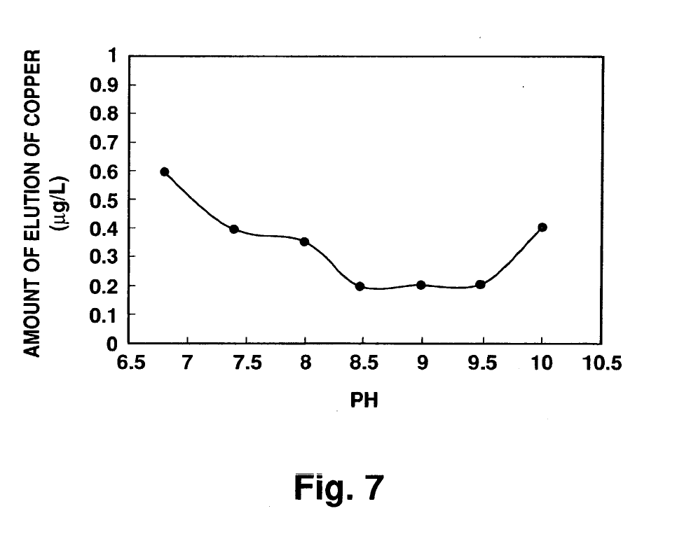

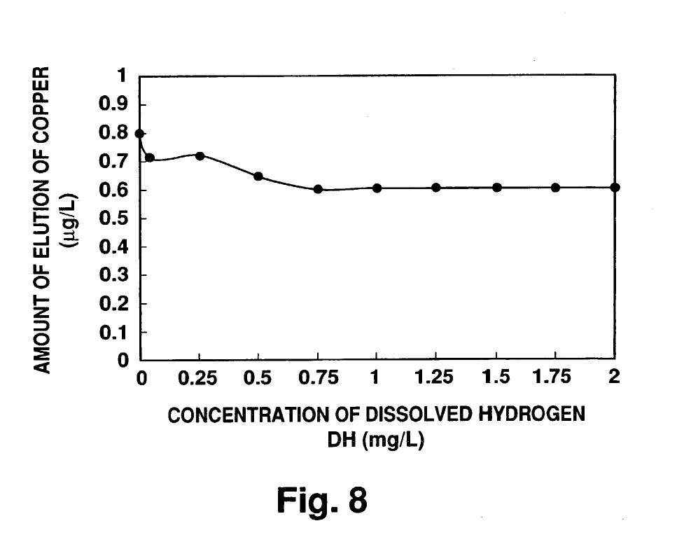

The results obtained by the present invention will now be described referring to FIGS. 7 and 8 and Tables 2, 3, and 4.

Table 2 shows concentrations of hydrogen peroxide and TOC in primary deionized water, high-purity water processed with ultraviolet oxidation treatment, and high-purity water processed with ultraviolet oxidation treatment and hydrogen peroxide removal treatment using a palladium catalyst and then sent in front of the cartridge polisher. As shown in Table 2, for the primary deionized water which is not subjected to ultraviolet oxidation treatment, hydrogen peroxide concentration was 2 μg/L or less, the value of 2 μg/L being the minimum limit of detection, and thus, hydrogen peroxide was not found. In the high-purity water subjected to the ultraviolet oxidation treatment, hydrogen peroxide was found in a concentration of 14 μg/L. With regard to TOC, because of the ultraviolet oxidation treatment, TOC is decomposed and the TOC concentration is reduced from 11 μg/L to 0.3 μg/L. For the high-purity water with reduction treatment using the palladium catalyst, the hydrogen peroxide concentration was less than or equal to the minimum limit of detection (less than or equal to 2 μg/L) and TOC concentration was 0.3 μg/L, which indicated that water having a quality suitable for inhibiting oxidation can be obtained at high purity.

TABLE 2

| | | HIGH-PURITY | |
|---|---|---|---|
| | | WATER (WITHOUT | HIGH-PURITY WATER |
| | PRIMARY | PALLADIUM | (WITH PALLADIUM |
| | DEIONIZED | CATALYST | CATALYST |
| | WATER | TREATMENT) | TREATMENT) |
| CONCENTRATION OF | <2 | 14 | <2 |
| HYDROGEN PEROXIDE | | | |
| CONCENTRATION OF | 11 | 0.3 | 0.3 |
| TOC | | | |

Table 3 shows results of measurements of the amount of elution of copper and the thickness of oxide film after a device to be immersed is immersed in an immersion tank for 10 minutes. The immersion tank was filled with five types of immersion water in each experiment: (1) high-purity water with the ultraviolet oxidation treatment; (2) high-purity water obtained by bypassing the ultraviolet oxidation device; (3) high-purity water obtained through ultraviolet oxidation device and palladium catalyst for removing hydrogen peroxide; (4) hydrogen-dissolved water obtained by allowing contact of water which passed through the ultraviolet oxidation device and palladium catalyst with hydrogen gas at a hydrogen dissolving section so that the concentration of dissolved hydrogen became 1.0 mg H/L; and (5) alkaline hydrogen-dissolved water obtained by adding ammonium hydroxide to hydrogen-dissolved water so that the pH is adjusted to 8.5, the hydrogen-dissolved water obtained by allowing contact of water which passed through the ultraviolet oxidation device and a palladium catalyst with hydrogen gas at a hydrogen dissolving section so that the concentration of dissolved hydrogen became 1.0 mg H/L. Two types of samples were prepared: 10 samples each of which is manufactured by forming a copper film on a surface of a silicon wafer by metal plating were prepared for determining the amount of elution of copper; and 10 samples each of which is manufactured by immersing a silicon wafer in a 0.5% hydrogen fluoride solution for 1 minute to remove the naturally formed oxide film for determining change in the thickness of oxide film. During the experiments, pH, ORP (oxidation-reduction potential), hydrogen peroxide concentration, and TOC concentration of each immersion water were also measured. The results indicated that for both inhibition of copper elution and inhibition of oxide film formation, water having no hydrogen peroxide, to which hydrogen is added, and having an alkaline characteristic was most effective. Of the two methods for obtaining high-purity water which does not contain hydrogen peroxide, no significant difference was observed between a method in which palladium catalyst is used after the ultraviolet oxidation treatment and a method in which the ultraviolet oxidation device is bypassed.

TABLE 3

| | | | (3) HIGH- | | |
|---|---|---|---|---|---|
| | (1) HIGH- | (2) HIGH-PURITY | PURITY | (4) HYDROGEN- | (5) ALKALI |
| | PURITY | WATER | WATER | DISSOLVED | HYDROGEN |
| | WATER (WITHOUT | (BYPASSING | (WITH | WATER | WATER |
| | PALLADIUM | ULTRAVIOLET | PALLADIUM | (HYDROGEN | (ALKALI |
| | CATALYST | OXIDATION | CATALYST | DISSOLVED | ADDED TO |
| | TREATMENT) | DEVICE) | TREATMENT) | INTO (3)) | (4)) |
| PH | 6.8 | 6.8 | 6.8 | 6.8 | 8.5 |
| ORP(mV vs. | +350 | +310 | +313 | −239 | −604 |
| NHE) | | | | | |
| HYDROGEN | 14 | <2 | <2 | <2 | <2 |
| PEROXIDE | | | | | |
| (μg/L) | | | | | |
| TOC | 0.3 | 9 | 0.3 | 0.3 | 0.3 |
| (μg/L) | | | | | |
| AMOUNT OF | 1.2 | 0.8 | 0.8 | 0.6 | 0.2 |
| COPPER | | | | | |
| ELUTION | | | | | |
| THICKNESS | 0.50 | 0.35 | 0.35 | 0.30 | 0.28 |
| OF OXIDE | | | | | |
| FILM | | | | | |

Table 4 shows changes in the concentration of dissolved hydrogen when the temperature of the water was varied and the measured values for the amount of copper elution in each case. The hydrogen-dissolved water used in this experiment was prepared by dissolving hydrogen into high-purity water obtained from primary deionized water in which the concentration of dissolved oxygen was controlled to 3 μg/L and which bypassed the ultraviolet oxidation device. During when hydrogen is dissolved, the feed pressure of hydrogen gas was maintained at a constant pressure of 1 kPa. By lowering the temperature of water to 15° C., the concentration of dissolved hydrogen was increased and inhibition effect on the copper elution was also observed.

TABLE 4

| | | | | |
|---|---|---|---|---|
| WATER TEMPERATURE (° C.) | 15 | 20 | 25 | 30 |
| CONCENTRATION OF DISSOLVED | 1.70 | 1.63 | 1.53 | 1.40 |
| HYDROGEN | | | | |
| AMOUNT OF COPER ELUTION | 0.5 | 0.6 | 0.7 | 0.9 |

The amount of copper elution was measured for cases where the concentration of the dissolved hydrogen in wash water was set at 1.0 ppm and the pH was varied. The results are shown on FIG. 7. The pH was adjusted using ammonium hydroxide (NH₃ 29%) (manufactured by KANTO KAGAKU). High-purity water processed with ultraviolet oxidation treatment and palladium catalyst was prepared as the water to be treated to which hydrogen was dissolved. In FIG. 7, the abscissa represents the pH and the ordinate represents the amount of elution of copper. The range of pH for this experiment was set from 6.8 for which no alkali is added to 10.0. The results indicated that significant effects for the inhibition of copper elution can be confirmed when the pH is raised approximately to 7.4, the copper elution can be inhibited maximally at a pH of approximately 8.5, the inhibition effects can continuously be obtained until a pH of approximately 9.5, and the elution of copper becomes significant again in more alkaline solution. The inhibition effects of corrosion of copper wirings were at the maximum with a pH of approximately 8.5.

Additional measurements for the amount of elution of copper were taken at a pH of 6.8 while the concentration of dissolved hydrogen in wash water was varied. The results are shown in FIG. 8. High purity water which was subjected to ultraviolet oxidation treatment and palladium catalyst was prepared as the water to be treated to which hydrogen is to be dissolved. In FIG. 8, the abscissa represents the concentration of dissolved hydrogen while the ordinate represents the amount of elution of copper. The range of concentrations of dissolved hydrogen was varied from a concentration of 0.00 mg/L in which no hydrogen is dissolved to a concentration of 2.00 mg/L in which hydrogen is dissolved in supersaturation. The results indicated that the inhibition effects of elution of copper were observed up to a concentration of dissolved hydrogen of 0.50 mg/L and no difference in the effects was observed when the concentration of dissolved hydrogen was increased beyond this value. However, after the concentration of dissolved hydrogen exceeded the saturation solubility, visible bubbles were observed adhering to the substrate surface.

In the above experiments, the following experimental apparatuses were used. An 8-inch silicon wafer was used as the semiconductor substrate. A high-purity water production apparatus of 1.2 m³/h manufactured by Organo Corporation was used. As the hydrogen-dissolved water producing apparatus, “SAN KAN OH H type 2400” manufactured by Organo Corporation was used. In this hydrogen-dissolved water producing apparatus, “SAN KAN OH H”, it is possible to efficiently produce hydrogen-dissolved water by allowing contact, through the use of a hollow fiber membrane, of the water to be treated with very high purity hydrogen gas produced by electrolysis of deionized water. The measuring apparatuses for pH, oxidation-reduction potential (ORP), and concentration of dissolved hydrogen used in the experiments were all apparatuses manufactured by DKK-TOA Corporation having model numbers respectively of HM-12P, RM-14P, and DHDI-1. The conditions for producing the hydrogen-dissolved water were as follows. The pressure of water to be treated was 0.1 MPa, the concentration of dissolved oxygen in the water to be treated was 2 μg/L, the feed pressure of hydrogen gas was 1 kPa, and the water temperature was 20° C.

According to the present invention, a hydrogen-dissolving apparatus for dissolving hydrogen into deionized water or high-purity water in an air-tight system is provided for performing wash or immersion process of semiconductor devices using hydrogen-dissolved water obtained by such apparatus.

According to an apparatus for producing wash or immersion water of the present invention, an advantage can be obtained that it is possible to efficiently produce wash or immersion water with a simple device structure.

Moreover, according to the present invention, it is possible to perform a wash or immersion process which can realize stable manufacturing of high performance products by inhibiting unexpected oxidation of semiconductor devices.

What is claimed is:

1. An apparatus for producing wash water or immersion water for semiconductor devices, said apparatus comprising:
a deionized water producing device for producing deionized water;
a hydrogen-dissolved water preparation device for preparing hydrogen-dissolved water by adding, in an air-tight system hydrogen to the deionized water produced by said deionized water producing device; and
a transport line for conveying the hydrogen-dissolved water prepared by the hydrogen-dissolved water preparation device to a wash apparatus or an immersion apparatus used in manufacturing of a semiconductor device, wherein
the hydrogen-dissolved water discharged out of the transport line is made in contact with a semiconductor device in said wash apparatus or said immersion apparatus so that oxidation of said semiconductor device is inhibited.

2. An apparatus according to claim 1, further comprising:
a palladium catalyst section upstream of or downstream of said hydrogen-dissolved water preparation device, wherein
said deionized water or said hydrogen-dissolved water is conveyed to said transport line via said palladium catalyst section.

3. An apparatus according to claim 1, further comprising;
an alkali solution adding section for adding an alkali solution to said hydrogen-dissolved water, wherein
the oxidation-reduction potential of the hydrogen-dissolved water is lowered through the addition of an alkali solution by said alkali solution adding section.

4. An apparatus according to claim 1, further comprising:
a ultraviolet oxidation section for irradiating ultraviolet rays onto said deionized water;
a bypass line for conveying said deionized water while bypassing said ultraviolet oxidation section; and
a switching device for selecting, for supplying to said hydrogen-dissolved water crating device, the deionized water which has passed through said ultraviolet oxidation section or the deionized water supplied through said bypass line.

5. An apparatus according to claim 1, further comprising:
a temperature controlling section for lowering the temperature of said deionized water supplied to said hydrogen-dissolved water preparation device.

6. An apparatus according to claim 1, wherein the concentration of dissolved hydrogen of said hydrogen-dissolved water is in a range from 50 μg/L to the saturation solubility.

7. An apparatus according to claim 3, wherein the pH of the hydrogen-dissolved water to which said alkali solution is added is in a range from 7.4 to 9.5.

8. An apparatus according to claim 1, wherein said semiconductor device is a semiconductor device in a formation process of a gate insulated film of a MOS transistor.

9. An apparatus according to claim 1, wherein said semiconductor device is a semiconductor device in a formation process of a contact hole for exposing a silicon surface.

10. An apparatus according to claim 1, wherein said semiconductor device is a semiconductor device in a formation process of a wiring layer made of a metal including copper or in an etching process of an insulated film formed on a wiring made of a metal including copper.

11. A method for washing or immersing a semiconductor device comprising the steps of:
producing deionized water;
preparing hydrogen-dissolved water by adding hydrogen to the produced deionized water in an air-tight system;
conveying the prepared hydrogen-dissolved water to a wash apparatus or an immersion apparatus used in manufacturing of a semiconductor device and washing or immersing the semiconductor device using said hydrogen-dissolved water; and
inhibiting oxidation of said semiconductor device during wash in said wash apparatus or during immersion in said immersion apparatus.

12. A method according to claim 11, wherein
a palladium catalyst section is provided upstream of or downstream of said hydrogen-dissolved water preparation device; and
said deionized water or said hydrogen-dissolved water is conveyed to said wash apparatus or to said immersion apparatus via the palladium catalyst section.

13. A method according to claim 12, further comprising the step of adding an alkali solution to said hydrogen-dissolved water to lower the oxidation-reduction potential of said hydrogen-dissolved water.

14. A method according to claim 11, wherein
a ultraviolet oxidation section for irradiating ultraviolet rays onto said deionized water and a bypass line for conveying said deionized water while bypassing said ultraviolet oxidation section are provided; and
either the deionized water which has passed through the ultraviolet oxidation section or the deionized water supplied through said bypass line is selected and supplied to said hydrogen-dissolved water preparation section.

15. A method according to claim 11, further comprising the step of lowering the temperature of said deionized water supplied to said hydrogen-dissolved water preaparation section.

16. A method according to claim 11, wherein the concentration of dissolved hydrogen in said hydrogen-dissolved water is adjusted in a range from 50 μg/L to the saturation solubility.

17. A method according to claim 13, wherein the pH of said hydrogen-dissolved water to which said alkali solution is added is in a range from 7.4 to 9.5.

18. A method according to claim 11, wherein said semiconductor device which is washed or immersed is a semiconductor device in a formation process of a gate insulated film of a MOS transistor.

19. A method according to claim 11, wherein said semiconductor device which is washed or immersed is a semiconductor device in a formation process of a contact hole for exposing a silicon surface.

20. A method according to claim 11, wherein said semiconductor device which is washed or immersed is a semiconductor device in a formation process of a wiring layer which is made of a metal including copper or a semiconductor device in an etching process of an insulated film formed over a wiring which is made of a metal including copper.
